(19) United States
(12) Patent Application Publication
(10) Pub. No.: US 2012/0075826 A1
(43) Pub. Date: Mar. 29, 2012

(54) PRESSURE SUPPORT FOR AN ELECTRONIC CIRCUIT

(76) Inventors: Michael Kaspar, Putzbrunn (DE); Herbert Schwarzbauer, Munchen (DE); Norbert Seliger, Zorneding (DE)

(21) Appl. No.: 13/262,582

(22) PCT Filed: Mar. 30, 2010
(86) PCT No.: PCT/EP2010/054147

§ 371 Date: Sep. 30, 2011

(30) Foreign Application Priority Data
Apr. 1, 2009 (DE) 10 2009 015 757.3

(51) Int. Cl. H05K 7/02

(52) U.S. Cl. 361/809

(57) ABSTRACT

A circuit design includes an electrical circuit, which has at least one electronic component attached to a substrate and a flat conductor track electrically contacting the component. An elastic element is provided on the electrical circuit and a device applies a force to the elastic element so that the elastic element is pressed onto the electrical circuit. Thus, crack formation in a solder under the component is prevented.

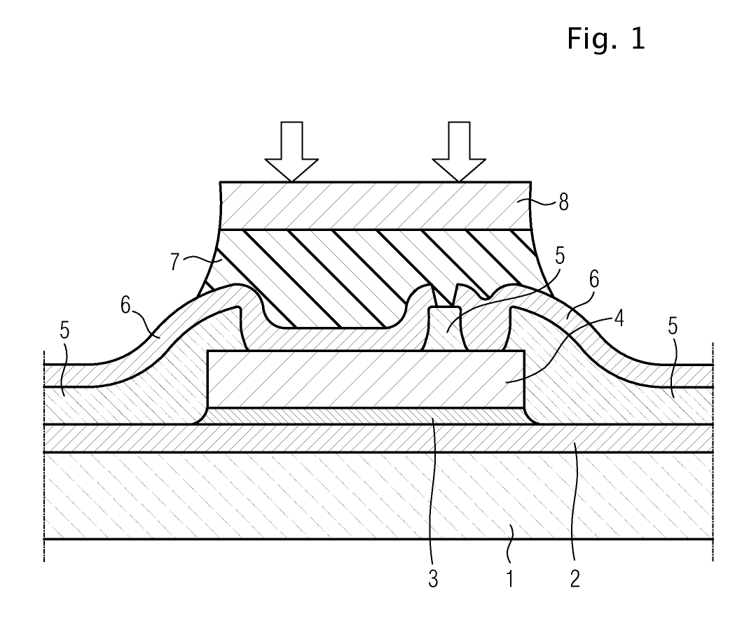

### CROSS REFERENCE TO RELATED APPLICATIONS

This application is the U.S. national stage of International Application No. PCT/EP2010/054147, filed Mar. 30, 2010 and claims the benefit thereof. The International Application claims the benefits of German Application No. 102009015757.3 filed on Apr. 1, 2009, both applications are incorporated by reference herein in their entirety.

### BACKGROUND

Described below is a circuit design including an electrical circuit, having at least one electronic component, especially a power electronics component attached to a substrate.

Power semiconductor chips are usually soldered to carriers made of metal or metalized ceramic, to enable them to rapidly dissipate into the environment heat occurring during operation. Frequent changes in temperature during operation cause cracks to develop in the solder over the long term from the edges inwards or a network of cracks to develop in the middle below the chip in the hottest area. This in turn worsens the heat dissipation, which leads to an increase in the temperature and thus shortens the life of the circuit.

### SUMMARY

A circuit design is described in which an increased resistance to heat-related cracks in the solder layer is provided.

The electrical circuit is based on a substrate, which can for example be a ceramic substrate with a metallic coating, for example a DCB. Fully-metallic substrates or the other known substrates can likewise be used.

One or more electronic components are attached to the substrate. The components may be one or more semiconductor components, especially power semiconductor components such as IGBTs for example. The components are connected to the substrate on their lower side via a layer of solder. Electrical contact is established at least partly on the upper side by one of more planar conductor tracks. The planar conductor tracks in this case may be layers, for example copper-based layers which have been created galvanically on the substrate and on the component or components for example.

An elastic element is provided on the electrical circuit. The elastic element can be a layer or a piece of silicon or a silicon adhesive for example. It is possible here for the elastic element to have a fixed connection to the electrical circuit, in the case of a silicon adhesive for example, but also for there to be no fixed connection, for example with a piece of silicon placed on the substrate or an insulating foil. Expediently the elastic element is electrically-insulating.

Finally a facility, or pressure element, for exerting a force on the elastic element is present. The effect of the force is to press the elastic element onto the electrical circuit.

In a method for operating an electrical circuit, including at least one electronic component attached to a substrate, an elastic element on the component, at least large enough to cover the entire component, is pressed onto the electrical circuit so that the pressure exerted acts on the entire component.

The pressure, which may be slight, on the electrical circuit, specifically on the component or components, has the advantageous effect that the cracks described in the introduction above in the solder layer below the component or the components to which the pressure is applied do not occur or are closed up again. This exploits the fact that the solder below the component or the components usually does not become brittle even during operation of the electrical circuit, but retains slight flow or creep capabilities. A crack forming is closed up again by a movement of the solder effected by the pressure. The elastic element advantageously ensures in such cases that there is an even distribution of the force on the component or the components.

In this case it is advantageous for the pressure in the area to be at fewer bar, i.e. between 1 and 10 bar in the area for example. The result of this is that on the one hand the pressure is sufficient to prevent the formation of cracks. On the other hand the solder is also not squeezed out from under the components.

The elastic element laterally may be at least the size of the component or one of the components so that, for at least one component, a planar pressure is exerted on the entire component. The lateral size in this case means the length and the width of the component, i.e. the extension in the plane defined by the substrate. In accordance with an embodiment, the elastic element is essentially laterally precisely as large as the overall electrical circuit. In other words the elastic element covers at least largely the overall electrical circuit so that a pressure is exerted on all components. The pressure is distributed evenly in this way and the formation of cracks is suppressed for all components present.

The electrical circuit includes the least one insulation layer, for example in the form of a structured insulation foil. This is located for example below the planar conductor track and prevents undesired electrical contacts. A stacked design with a number of insulation layers and a number of layers of planar conductor tracks is possible in this case. The insulation layer itself can likewise also have a stacked design with a number of individual layers, for example a number of insulating foils. The insulating layer may be structured to produce a through-contacting from upper-side contact surfaces on the components to the planar conductor track.

The elastic element may be softer than the material of the insulation layer. This avoids the mechanical overloading of the insulation layer through the elastic element pressing onto it. In order to once again bring about an even pressure on the elastic element, the facility may have a largely non-elastic pressure piece made of metal, ceramic or plastic for example, which itself is arranged to exert the pressure on the elastic element.

It is especially advantageous for the elastic element to have good thermal conductivity. For example it may have the thermal conductivity of at least 1 W/mK. Heat which arises in the components is then dissipated not only downwards into the substrate but also up into the elastic element and thus the overall dissipated thermal power is increased. This is especially advantageous for power electronic components with high heat dissipation. In this case it can be advantageous for the elastic element to have a small thickness in order to present a small thermal resistance for transporting away heat into the pressure piece for example. Furthermore it is advantageous for the pressure piece itself to also have good thermal conductivity in this case, to be made of metal for example.

It is also very advantageous for the elastic element to be designed so that it functions as a heat store. For this purpose a sufficient mass, i.e. a sufficient thickness is necessary. For example the thickness of the elastic element should amount to at least 3 mm. In this embodiment the elastic element can serve as an intermediate heat store and in this way ameliorate short-term peaks in the heat dissipated by the component or components. The life of the components is increased by this.

### BRIEF DESCRIPTION OF THE DRAWINGS

These and other aspects and advantages will become more apparent and more readily appreciated from the following description of the exemplary embodiments, taken in conjunction with the accompanying drawing.

The single FIGURE in this case shows an electrical circuit with a power electronics module.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The FIGURE shows a typical electrical circuit with a power semiconductor component 4. The power semiconductor component 4 is attached by a solder layer 3 to a DCB copper track 2. The DCB copper track 2 itself is a part of a DCB substrate, which in this example includes the DCB copper track 2, which is attached to a ceramic carrier 1.

In this exemplary embodiment the contact between the power semiconductor component 4 is established on the upper side by a planar copper track 6. For this an insulation layer 5 is first provided on the substrate and the power semiconductor component 4. The insulation layer 5 in this exemplary embodiment is a laminated-on insulating film. The insulation layer 5 can however also be created in other ways, by known chemical or physical deposition methods for example.

To make electrical contact to the power semiconductor component 4 possible, the insulation layer 5 has one or more windows. The windows can be created by a structuring of the insulation layer 5 on the electrical circuit, by laser ablation for example. But it is also possible for example to laminate an already pre-structured film onto the circuit.

The planar copper conductor track 6 is attached to the insulation layer 5. The planar copper conductor track 6 can likewise be created in a number of ways, for example by the known deposition methods. However an expedient method in the field of power electronics is creation by galvanic deposition. This is the best way of enabling the thickness needed for high currents to be provided. The planar copper conductor track 6 is likewise itself structured in this exemplary embodiment, since a plurality of electrical connections have to be contacted independently.

A silicon adhesive layer 7 is present on the planar copper conductor track 6. The silicon adhesive layer 7 roughly corresponds in its length and width to the power semiconductor component 4. The silicon adhesive layer 7 is electrically insulating, but is designed in this exemplary embodiment to have a thermal conductivity of 10 W/mK, i.e. to have comparatively good thermal conductivity for an insulator. The thickness of the silicon adhesive layer 7 amounts in this exemplary embodiment to around 0.5 mm. Provided above the silicon adhesive layer 7 is a pressure piece 8 made of metal. A pressure is exerted by this pressure piece 8 on the silicon adhesive layer 7 lying below it. The pressure on the pressure piece 8 is exerted in this case by a corresponding design of the housing for the electrical circuit. The silicon adhesive layer 7 distributes this pressure to the structures lying below it, i.e. via the planar copper conductor track 6 and the insulation layer 5 to the power semiconductor component 4 and via this in its turn to the solder layer 3.

Ultimately the solder layer 3 is thus put under pressure. This pressure is “light”. It should expediently be such that on the one hand cracks arising in the solder layer 3 close again. On the other hand it should not be strong enough for the solder below the power semiconductor components 4 to be pushed out under its effect. The pressure effect is based on the solder, even in the completed state of the electrical circuit retaining a certain, even if only small, flow capability. If operation at changing temperatures now leads over the course of time to a small crack forming, the solder creeps under the influence of the slight pressure back into the crack and closes it up again. Thus the negative influence of the cracks which usually otherwise form is avoided and the life of the overall module is greatly increased.

The comparatively small thickness of the silicon adhesive layer 7 and its high thermal conductivity lead in this exemplary embodiment to a significant amount of waste heat from the power semiconductor components 4 being able to be dissipated by the silicon adhesive layer 7. The silicon adhesive layer 7 and the pressure piece 8 thus serve in an advantageous manner as additional heat sinks for the power semiconductor component 4.

A second alternative embodiment is produced if the silicon adhesive layer 7 is designed as a thermal buffer. For this the silicon adhesive layer 7 is expediently embodied much thicker than in the first exemplary embodiment, for example 3 mm or 5 mm thick. As an alternative to the silicon adhesive layer 7 in this case an elastic element, not shown in the FIGURE, formed of silicon or of another heat-resistant elastic material, can be used, but which is not necessarily glued to the surface of the planar copper conductor track 6. The silicon adhesive layer 7 or the element then serve as heat buffers. A superfluity of waste heat which arises within a short period of peak power in the power semiconductor element 4 is stored in the element or the silicon adhesive layer 7 and then gradually dissipated. In this alternative the elastic element or the silicon adhesive layer 7 thus advantageously serve to accommodate peaks in the waste heat generation, which likewise leads to an increase in the life.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-10. (canceled)

11. A circuit device, comprising:
an electrical circuit having at least one electronic component attached to a substrate by a solder layer and at least one planar conductor track electrically contacting the component, the planar conductor track, at least in parts, running on a side of electronic the component facing away from the substrate;
an elastic element provided on the electrical circuit; and
a pressure element exerting a force on the elastic element so that the elastic element is pressed onto the electrical circuit.

12. The circuit design as claimed in claim 11, wherein the elastic element is at least in parts formed from a material selected from the group consisting of silicon and silicon adhesive.

13. The circuit design as claimed in claim 12, wherein the elastic element has a lateral dimension that is at least as large as a lateral dimension of the at least one electrical component.

14. The circuit design as claimed in claim 13, wherein the elastic element has a lateral dimension that is at least as large as a lateral dimension of the electrical circuit.

15. The circuit design as claimed in claim 14, wherein the pressure element comprises a pressure piece, formed from a material selected from the group consisting of metal, ceramic and plastic, disposed above the elastic element.

16. The circuit design as claimed in claim 15, further comprising an insulation layer under the planar conductor track.

17. The circuit design as claimed in claim 16, wherein the elastic element is softer than the insulating layer.

18. The circuit design as claimed in claim 17, wherein the elastic element has a thermal conductivity of at least 1 W/mK.

19. The circuit design as claimed in claim 18, wherein the at least one electronic component includes a power semiconductor component.

20. The circuit design as claimed in claim 11, wherein the elastic element has a lateral dimension that is at least as large as a lateral dimension of the at least one electrical component.

21. The circuit design as claimed in claim 11, wherein the elastic element has a lateral dimension that is at least as large as a lateral dimension of the electrical circuit.

22. The circuit design as claimed in claim 11, wherein the pressure element comprises a pressure piece, formed from a material selected from the group consisting of metal, ceramic and plastic, disposed above the elastic element.

23. The circuit design as claimed in claim 11, further comprising an insulation layer under the planar conductor track.

24. The circuit design as claimed in claim 23, wherein the elastic element is softer than the insulating layer.

25. The circuit design as claimed in claim 11, wherein the elastic element has a thermal conductivity of at least 1 W/mK.

26. The circuit design as claimed in claim 11, wherein the at least one electronic component includes a power semiconductor component.

27. A method for operating an electrical circuit having at least one electronic component attached to a substrate by a solder layer, and an elastic element on the component, comprising:
exerting a force by the elastic element onto the electrical circuit, the elastic element having a lateral dimension at least large enough to cover all of the at least one component and exert pressure on all of the at least one component.
